(19) United States
(12) Patent Application Publication
(10) Pub. No.: US 2018/0139871 A1
(43) Pub. Date: May 17, 2018

(54) COOLING ARRANGEMENT FOR A POWER SUPPLY MODULE

(71) Applicant: TDK-LAMBDA LTD, Karmiel Industrial Zone (IL)

(72) Inventors: Miki Stravets, Kiryat Motzkin (IL); George Rucareanu, Nesher (IL)

(73) Assignee: TDK-LAMBDA LTD, Karmiel Industrial Zone (IL)

(21) Appl. No.: 15/432,238

(22) Filed: Feb. 14, 2017

(30) Foreign Application Priority Data
Nov. 16, 2016 (IL) 249005

(51) Int. Cl. H05K 7/20; H02M 7/00

(52) U.S. Cl. CPC H05K 7/20909; H02M 7/003

(57) ABSTRACT

A power supply module for facilitating an increased flow of cooling air comprises a chassis in which circuitry of the power supply module is housed, and a front panel associated with the chassis. The power supply module is configured with one or more airflow openings which facilitate a flow of cooling air into or out of a chassis interior and which are ensured of remaining unblocked, wherein one of the chassis and the front panel is formed with one or more inclined surfaces to define at least a part of a corresponding passageway through which air crossing a portion of the front panel is flowable. The one or more inclined surfaces is apertured to define the one or more airflow openings or an aperture in fluid communication with the one or more airflow openings.

### FIELD OF THE INVENTION

The present invention relates to the field of power supply modules. More particularly, the invention relates to a cooling arrangement for such devices.

### BACKGROUND OF THE INVENTION

Power supply modules for converting AC power to DC power are generally characterized by the presence of heat-generating components, including an inverter for converting rectified DC power to high frequency power and a transformer for lowering the voltage of the high frequency power. The lowered-voltage power is then converted into DC power by an output rectifier circuit, enabling the DC power to be applied to a load. Efficient operation of a power supply module requires dissipation of the generated heat, generally by means of cooling air that flows through the interior of the power supply module.

However, the front panel of a chassis in which the electronic components of a power supply module are housed is generally equipped with control elements for setting desired values of input and output voltage or other parameters of importance, such as switches, knobs and buttons, and with a display screen or LED indicators, thereby reducing the available area on the front panel for the provision of air flow openings.

Due to the limited number of air flow openings in the front panel, the housed electronic components many times experience unwanted heating that leads not only to a decrease in efficiency, but also to power supply malfunction.

A power supply module is often rack mounted. A rack is a type of frame that facilitates the stacking of electronic devices, including power supply modules, one on top of the other. For many industrial applications, a rack typically, but not necessarily, having a width of 19 inches is used for the compact stacking of a rectangular chassis that houses an electronic device. Each chassis is releasably coupled to the rack, such as by horizontal rails that are engageable with a corresponding side of the chassis, in order to be selectively extended and retracted upon demand so that maintenance or service operations may be performed.

While operating, a rack mounted power supply module becomes heated and needs to be continuously cooled. Since each chassis is stacked in close proximity to, and is generally in abutting relation with, an overlying chassis, thereby restricting or altogether preventing the passage of cooling air into the chassis from above or from below, and is coupled to the rack from the side, thereby restricting or altogether preventing the passage of cooling air into the chassis from the side, the only practical way the power modules are able to be cooled is via air flow openings formed in a front panel of the chassis. However, the available area on the front panel for the provision of air flow openings is limited, as described above.

It is an object of the present invention to provide a front panel configuration that facilitates an increased influx relative to the prior art of cooling air into a chassis within which heatable electronic components of a power supply module are housed.

Other objects and advantages of the invention will become apparent as the description proceeds.

### SUMMARY OF THE INVENTION

The present invention provides a power supply module for facilitating an increased flow of cooling air, comprising a chassis in which circuitry of the power supply module is housed, and a front panel associated with said chassis, wherein the power supply module is configured with one or more airflow openings which facilitate a flow of cooling air into or out of a chassis interior and which are ensured of remaining unblocked, wherein one of the chassis and the front panel is formed with one or more inclined surfaces to define at least a part of a corresponding passageway through which air crossing a portion of the front panel is flowable, wherein said one or more inclined surfaces is apertured to define said one or more airflow openings or an aperture in fluid communication with said one or more airflow openings.

In one embodiment, one of the chassis and the front panel is formed with said one or more airflow openings which are recessed from said inclined surface and through which the vertical flow of cooling air is flowable.

The inclined surface is of much utility when a portion thereof is in abutting relation with a corresponding portion of an additional power supply module that is vertically spaced thereto, causing the cooling air to flow through the passageway and the one or more airflow openings of both the power supply module and the additional power supply module.

In one aspect, one of the inclined surfaces in vertical cross section extends from an interface of the chassis and front panel to a vertical edge of a vertically oriented element of the front panel formed with a plurality of vertically spaced unrecessed air flow openings and which is vertically spaced from said interface.

In one aspect, the power supply module is rack mounted, wherein the one or more airflow openings are ensured of remaining unblocked by the rack on which the power supply module is mounted or by any other device mounted onto the rack. One of the inclined surfaces in horizontal cross section may extend from an interface of the chassis and front panel that is adjacent to a side bracket for mounting the power supply module to the rack to a forward edge of a vertically oriented element of the front panel which is laterally spaced from said interface.

The front panel may be coupled with the chassis, or may be integrally formed with the chassis.

### BRIEF DESCRIPTION OF THE DRAWINGS

In the drawings:

FIG. 1 is a perspective view from the side of a prior art front panel for a power supply module;

FIG. 2 is a perspective view from the side of a front panel for a power supply module, according to one embodiment of the invention;

FIG. 2A is a perspective view from the side of a front panel for a power supply module, according to another embodiment of the invention;

FIG. 3 is a perspective view from above of a portion of a rack mountable power supply module, according to another embodiment of the invention;

FIG. 4 is a perspective view from the bottom of a portion of the rack mountable power supply module of FIG. 3;

FIG. 5 is a front view of the power supply module of FIG. 3;

FIG. 6 is a side view of a portion of the power supply module of FIG. 3, shown without an L-bracket; and

FIG. 7 is a side view of a portion of two stacked power supply modules of FIG. 6.

### DETAILED DESCRIPTION OF PREFERRED EMBODIMENTS

The present invention is a novel increased air influx facilitating configuration for a front panel of a chassis that houses a power supply module.

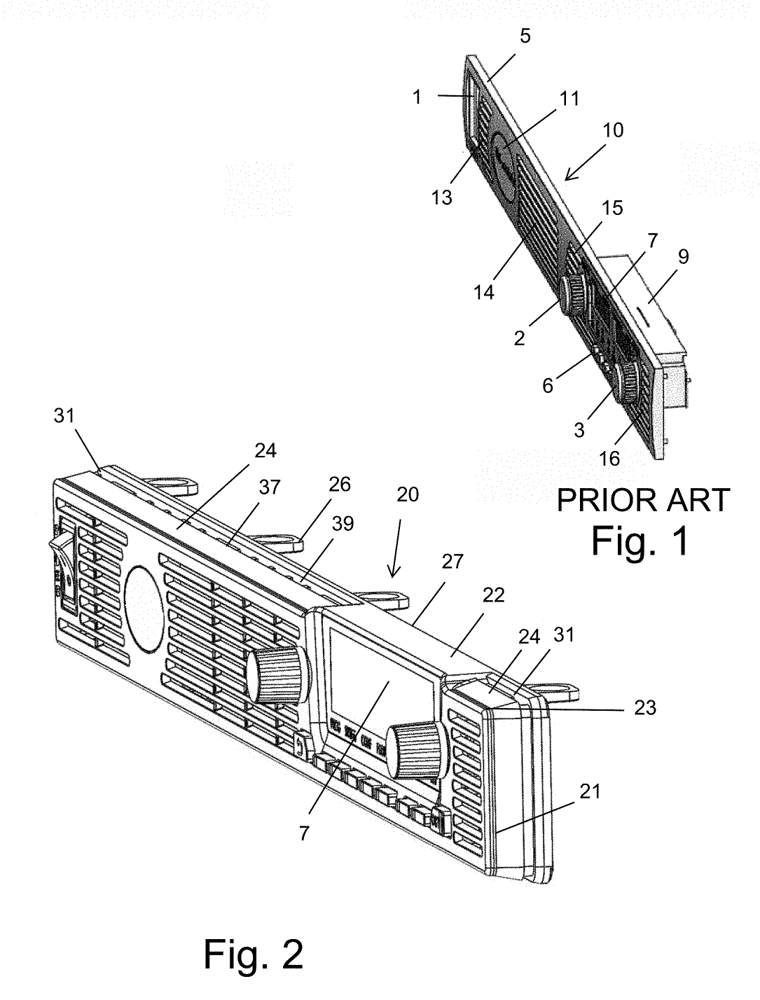

Reference is first made to FIG. 1, which illustrates a prior art front panel 10 of a power supply chassis. Prior art front panel 10 comprises a thin and rigid board 5 from which protrude a plurality of user interface elements, including switch 1, knobs 2 and 3, and buttons 6. One or more display screens 7 for viewing output information in response to a selectively manipulated user interface element are embedded within board 5 between knobs 2 and 3. When front panel 10 is fully coupled to the dedicated chassis, a circuit is closed between interface element circuitry within housing 9 at the rear of board 5 and the circuitry of the electronic device housed in the chassis, allowing the user interface elements to control operation of the power supply module.

Due to the limited surface area of board 5, the positioning of manufacturer-distinctive indicia at region 11 and the large number of user interface elements interspersed throughout the board, only four areas 13-16 of vertically spaced air flow openings are provided within board 5.

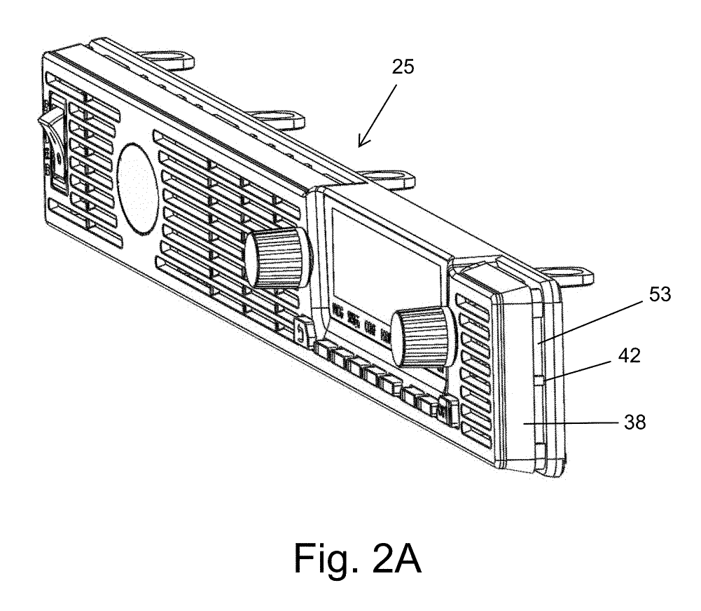

FIG. 2 illustrates a front panel 20, according to one embodiment of the invention, which is configured with additional air flow openings to enable not just horizontal air inflow, but also vertical air inflow, into the chassis interior. Front panel 20 may be coupled with a dedicated power supply chassis, such as by fasteners insertable through corresponding eyelets 26 or by other means, or alternatively may be used to retrofit an existing chassis.

To accommodate the additional air flow openings, front panel 20 is configured with different types of upper surfaces. The first type is a basic horizontal surface 22, which is perpendicular to vertically oriented display screen 7 and which may overly the interface element circuitry housing. The second upper surface type is an inclined surface 24, which extends downwardly from the rear edge 27 of basic surface 22 until coinciding with a front surface 21 of front panel 20, at an upper edge 23 thereof. Front panel 20 is shown to comprise two inclined surfaces 24 between which basic surface 22 is interposed.

A longitudinally extending groove 31, i.e. in a direction along the length or long dimension of front panel 20, is formed in a central region of each inclined surface 24 between edges 23 and 27, and may be of the same length as the corresponding inclined surface 24. A third upper surface 37 is provided below, and recessed from, the corresponding inclined surface 24, and is formed with a plurality of longitudinally spaced air flow openings 39, which may be circular apertures or of any other desired shape. Third surface 37 may be, but not necessarily, parallel to inclined surface 24, as long as the vertical projection of the opposite edges of groove 31 onto third surface 37 coincides with an opening of each air flow opening 39, in order to maximize air intake.

Front panel 20 may also be provided with three types of lower surfaces which are symmetrical to the three upper surfaces, respectively, to accommodate downwardly facing air flow openings. It will be appreciated that front panel 20 may be provided with only downwardly facing air flow openings.

When front panel 20 has both upwardly facing and downwardly facing air flow openings, the side surfaces 36 of the front panel may be trapezoidal.

As shown in FIG. 2A, a front panel 25 may have trapezoidal side surfaces 38 that are formed with one or more recessed air flow openings 42 to facilitate sideways air inflow into the chassis interior. Each side surface 38 may be configured with a vertically extending groove 53 in fluid communication with each airflow opening 42 through which cooling air is flowable.

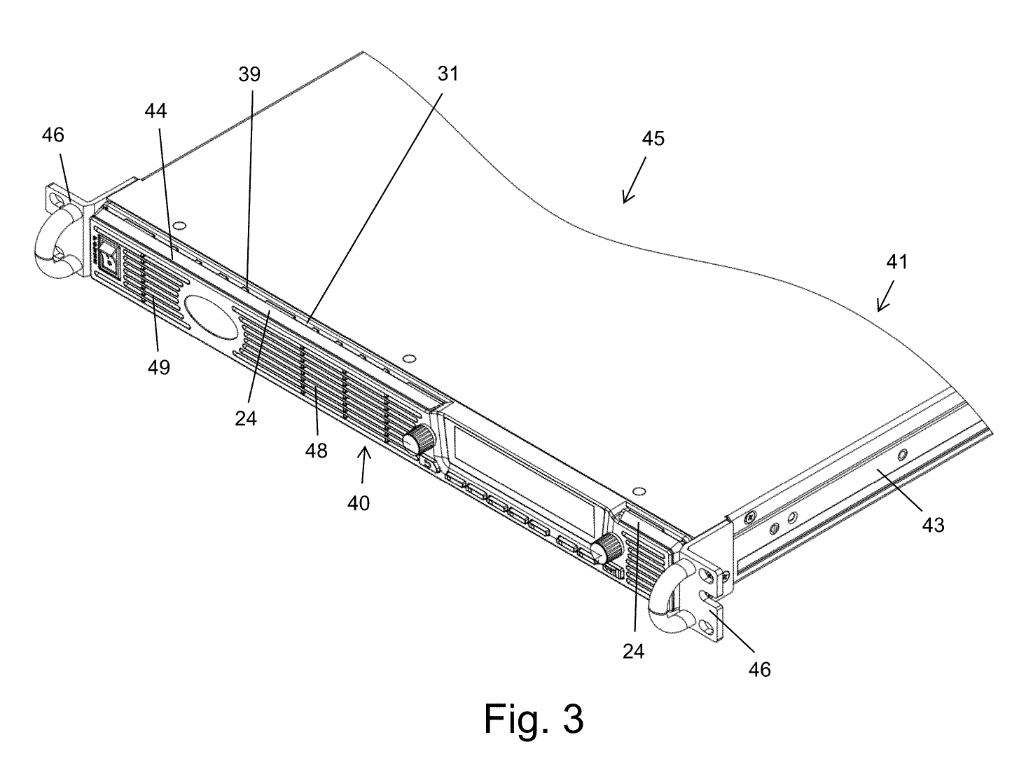

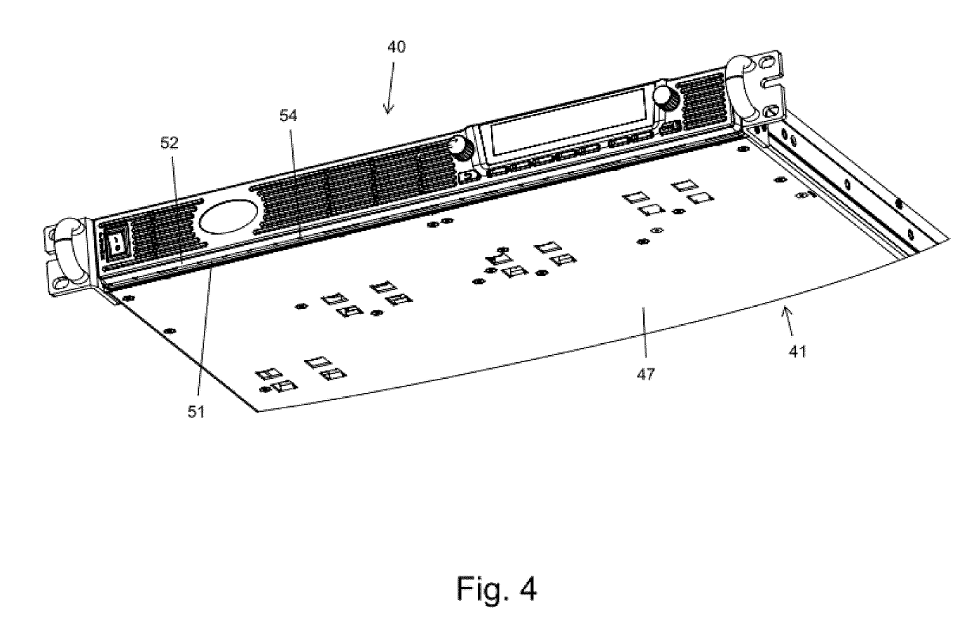

FIGS. 3 and 4 illustrate a power supply module 45 comprising a chassis 41, generally but not necessarily rectangular, having a front panel 40 being configured in accordance with the present invention. Front panel 40 may be integrally formed with chassis 41, or alternatively may be formed separately from chassis 41 and coupled thereto. Each side of chassis 41 may be provided with an elongated fixture 43 for connection to a sliding mechanism or a rail, which in turn is movably connected to a rack. An L-bracket 46 or the like which is laterally adjacent to front panel 40 may be fixedly connected to a corresponding chassis side, to facilitate secured mounting onto the rack. The connection to a sliding mechanism or a rail and to an L-bracket precludes the flow of sideways intake air into chassis 41.

Front panel 40 is configured with two upper inclined surfaces 24, which may be coplanar, to accommodate the provision of longitudinally spaced and upwardly facing air flow openings 39 which are recessed therefrom and are in communication with longitudinally extending groove 31. These upwardly facing air flow openings 39 are in addition to vertically spaced air flow openings 48, which are formed in vertically oriented board 49 located below upper edge 44 thereof coinciding with an upper inclined surface 24, for providing horizontal air inflow into chassis 41. Air flow openings 48 are located below and forwardly from upwardly facing air flow openings 39.

Front panel 40 is also configured with a lower surface 52 in which is formed longitudinally extending groove 51 being in communication with downwardly facing air flow openings 54. Lower surface 52 may be inclined, for example symmetrical to an upper inclined surface 24, or alternatively may be horizontally oriented so as to be substantially parallel to the lower surface 47 of chassis 41.

A filter element (not shown) may be provided with front panel 40, to prevent the infiltration of dust or other contaminants through the air flow openings, whether upwardly facing air flow openings 39, vertically spaced air flow openings 48, downwardly facing air flow openings 54, or all of the above.

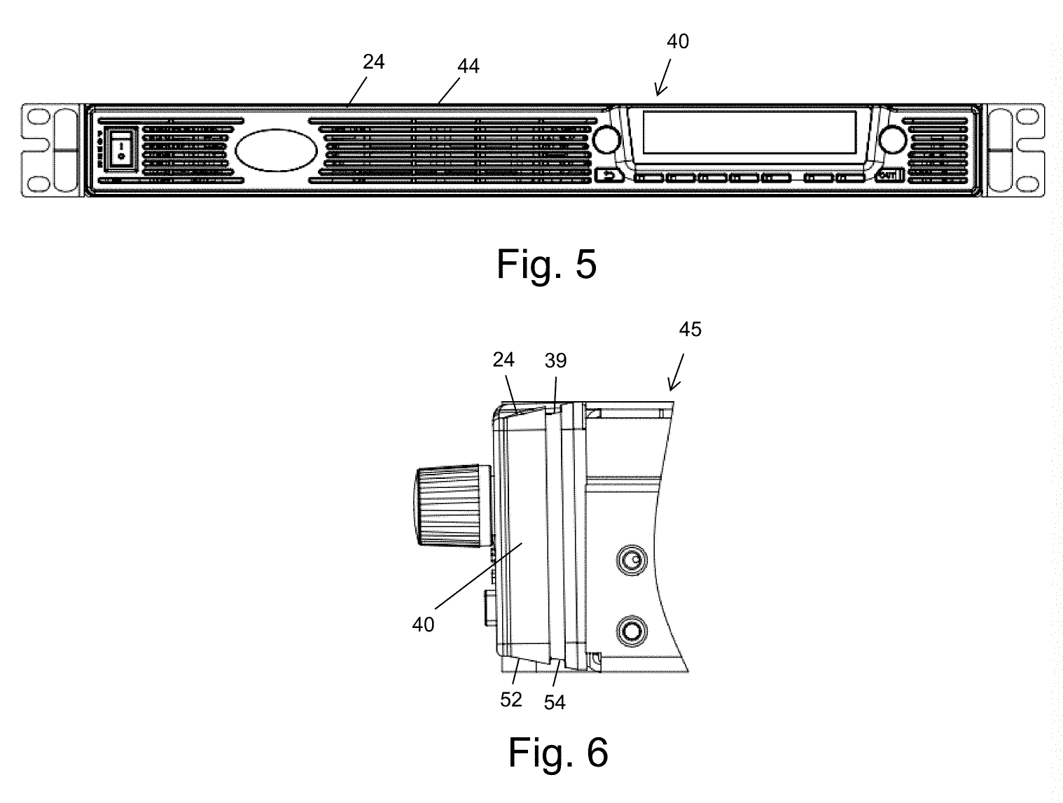

As shown in the front view of front panel 40 shown in FIG. 5, the upwardly facing air flow openings are not visible, being recessed from upper inclined surface 24 extending downwardly towards upper front board edge 44.

FIG. 6 illustrates a side view of a portion of power supply module 45 without an L-bracket. Front panel 40 is shown to have an inclined upper surface 24 and an inclined lower surface 52, making upwardly facing air flow openings 39 and downwardly facing air flow openings 54 accessible to ambient air.

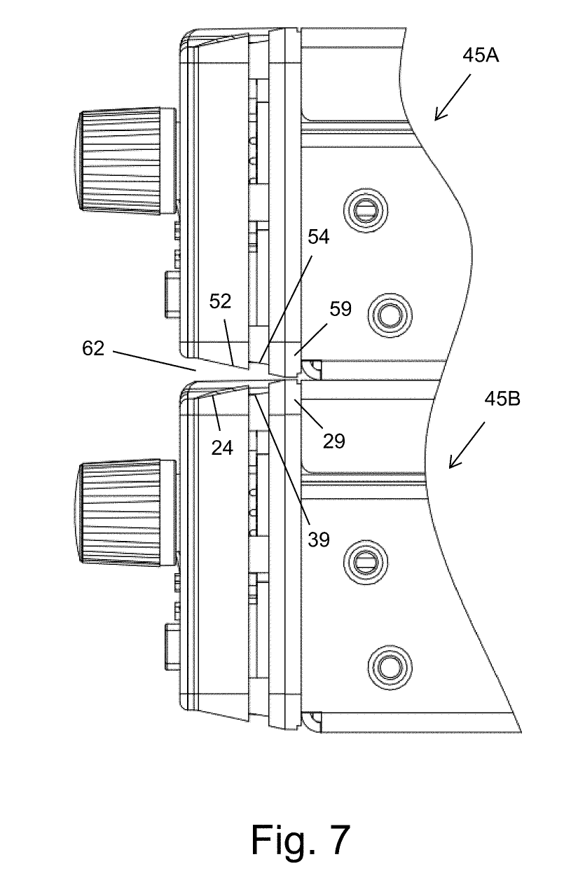

Thus when two rack-mounted power supply modules 45A-B are stacked one on top of the other as shown in FIG. 7, the ambient inflow air, after passing through passageway 62 defined by inclined upper surface 24 and an inclined lower surface 52, is blocked by abutting upper surface portion 29 and lower surface portion 59 of the front panel. This inflow air is thus urged to flow through downwardly facing air flow opening 54 of upper module 45A and upwardly facing air flow opening 39 of lower module 45B, through the chassis interior, and then through a rear chassis opening.

Although passageway 62 is shown to be defined by inclined upper surface 24 and an inclined lower surface 52, it will be appreciated that passageway 62 will also be defined when only one of upper surface 24 and an lower surface 52 is inclined.

In another embodiment of the invention, an inclined surface is formed in a side surface of the front panel to facilitate sideways air inflow. Although L-bracket 46 (FIG. 3) or the like is normally in contact with a side surface of the front panel, a chamfer-like inclined surface extending from an interface of the chassis side surface and front panel to the front surface of the front panel facilitates formation of an interspace between the bracket and the front panel. Thus when an elongated groove is formed in the chamfer-like inclined surface, airflow openings are able to be recessed and to receive sideways air inflow.

In another embodiment of the invention, the surface from which air flow openings are recessed may be formed in a dedicated surface of the chassis. This chassis surface formed with a longitudinally extending groove may be inclined at the same inclination as that of the abutting front panel surface, or at a different angle. Alternatively, the chassis surface formed with a longitudinally extending groove in communication with recessed air flow openings may be substantially horizontally oriented, as long as an opposed surface is inclined to define a passageway. A first surface of the passageway may be a part of a lower power supply module and a second surface of the passageway may be a part of an upper power supply module.

Alternatively, the surface formed with a plurality of longitudinally spaced air flow openings may be a part of the chassis while the surface in which the groove is formed may be a part of the front panel.

While some embodiments of the invention have been described by way of illustration, it will be apparent that the invention can be carried out with many modifications, variations and adaptations, and with the use of numerous equivalents or alternative solutions that are within the scope of persons skilled in the art, without exceeding the scope of the claims.

1. A power supply module for facilitating an increased flow of cooling air, comprising a chassis in which circuitry of the power supply module is housed, and a front panel associated with said chassis,
wherein said power supply module is configured with one or more airflow openings which facilitate a flow of cooling air into or out of a chassis interior and which are ensured of remaining unblocked,
wherein one of the chassis and the front panel is formed with one or more inclined surfaces to define at least a part of a corresponding passageway through which air crossing a portion of the front panel is flowable,
wherein said one or more inclined surfaces is apertured to define said one or more airflow openings or an aperture in fluid communication with said one or more airflow openings.

2. The power supply module according to claim 1, wherein one of the chassis and the front panel is formed with said one or more airflow openings which are recessed from said inclined surface and through which the flow of cooling air is flowable.

3. The power supply module according to claim 2, further comprising a surface recessed from the inclined surface which is elongated and is formed with a plurality of the one or more recessed airflow openings through which the cooling air is flowable.

4. The power supply module according to claim 2, wherein one of the inclined surfaces in vertical cross section extends from an interface of the chassis and front panel to a vertical edge of a vertically oriented element of the front panel formed with a plurality of vertically spaced unrecessed air flow openings and which is vertically spaced from said interface.

5. The power supply module according to claim 4, wherein the inclined surface is elongated and is formed with a longitudinally extending groove in fluid communication with the one or more recessed airflow openings through which the cooling air is flowable.

6. The power supply module according to claim 5, wherein the plurality of air flow openings are longitudinally spaced.

7. The power supply module according to claim 4, wherein the inclined surface extends downwardly from the interface and the one or more recessed airflow openings through which vertical inflow air is receivable are upwardly facing.

8. The power supply module according to claim 4, wherein the inclined surface extends upwardly from the interface and the one or more recessed airflow openings through which vertical inflow air is receivable are downwardly facing.

9. The power supply module according to claim 1, wherein the inclined surface is formed in the front panel.

10. The power supply module according to claim 1, wherein the inclined surface is formed in the chassis.

11. The power supply module according to claim 1, wherein a portion thereof is in abutting relation with a corresponding portion of an additional power supply module that is vertically spaced thereto, causing the cooling air to flow through the one or more airflow openings of both the power supply module and the additional power supply module.

12. The power supply module according to claim 11, wherein the additional power supply module comprises a chassis and a front panel, and both the power supply module and the additional power supply module are formed with an inclined surface to define together the passageway through which the cooling air is flowable.

13. The power supply module according to claim 2, wherein the cooling air is introduced through the one or more recessed airflow openings and exits from an opening provided at a rear region of the chassis.

14. The power supply module according to claim 2, wherein the cooling air is discharged from the one or more recessed airflow openings.

15. The power supply module according to claim 1, which is rack mounted, wherein the one or more airflow openings are ensured of remaining unblocked by the rack on which the power supply module is mounted or by any other device mounted onto the rack.

16. The power supply module according to claim 15, wherein one of the inclined surfaces in horizontal cross section extends from an interface of the chassis and front panel that is adjacent to a side bracket for mounting the power supply module to the rack to a forward edge of a vertically oriented element of the front panel which is laterally spaced from said interface.

17. The power supply module according to claim 1, wherein the front panel is coupled with the chassis.

18. The power supply module according to claim 1, wherein the front panel is integrally formed with the chassis.
